(19) United States
(12) Patent Application Publication
(10) Pub. No.: US 2006/0087226 A1
(43) Pub. Date: Apr. 27, 2006

(54) Organic LED vapor deposition mask

(76) Inventors: Tsutomu Miura, Yokohama (JP); Nobuyuki Mori, Saitama (JP)

Correspondence Address: Patent Legal Staff;Eastman Kodak Company, 343 State Street, Rochester, NY, 14650-2201, US

(21) Appl. No.: 11/244,979

(22) Filed: Oct. 6, 2005

(30) Foreign Application Priority Data
Oct. 26, 2004 (JP) 2004-310469

(51) Int. Cl. H05B 33/00; B05D 5/06; B05D 5/12

(52) U.S. Cl. 313/504; 313/503; 427/66

(57) ABSTRACT

A plate-shaped vapor deposition mask for use with an OLED substrate, the mask is provided with through holes corresponding to a plurality of organic light-emitting elements formed on the substrate, used in vapor deposition fabrication of these organic light-emitting elements stacked on the substrate comprising the mask having engagement sections provided over a wide range on the surface facing the substrate corresponding to the distribution of the through holes, the substrate formed with corresponding structures to prevent positional slip of the vapor deposition mask in an in-plane direction by engaging the engagement sections of the mask.

### FIELD OF THE INVENTION

The present invention relates to technology for manufacturing organic light emitting-elements on a substrate, and particularly to technology for carrying out vapor deposition with good precision.

### BACKGROUND OF THE INVENTION

An organic LED (light emitting diode) is a device provided with organic light emitting elements having the same light-emitting principal as an LED. By carrying out control to provide a plurality of organic light-emitting elements on the substrate, it is possible to manufacture a flat panel device (FPD) using an organic LED.

Formation of an organic light-emitting element is generally carried out by subjecting a substrate to vapor deposition processing. In this processing, first of all a vapor deposition mask having through holes corresponding to organic light-emitting elements is placed with a specified alignment precision (positional precision) on a glass substrate, and then adhered and held in on the glass substrate. An organic light-emitting element is then formed at a specified position on the substrate by carrying out vapor deposition of an organic layer on the glass substrate that has been masked inside a vapor deposition unit.

In Japanese patent laid-open No. 2002-220656, technology is disclosed for strengthening the periphery of a vapor deposition mask using a member having an appropriate thermal expansion coefficient.

### SUMMARY OF THE INVENTION

Because there is an increase in temperature at the time of vapor deposition inside the vapor deposition unit, microscopic thermal expansion accompanying rise in temperature occurs in the vapor deposition mask and the substrate. Generally, the extent of expansion between the two is different, and slip force in an in-plane direction due to expansion exceeds adhering and holding force. As a result, positional displacement arises between the mask and the substrate in an in-plane direction, and the extent of this displacement is proportional to the size of the glass substrate (vapor deposition mask).

An object of the present invention is to improve precision of vapor deposition of an organic LED.

Another object of the present invention is to avoid a situation where alignment precision between the substrate and the vapor deposition mask before vapor deposition is lowered at the time of vapor deposition.

In accordance with the present invention, a plate-shaped vapor deposition mask for use with an OLED substrate, the mask is provided with through holes corresponding to a plurality of organic light-emitting elements formed on the substrate, used in vapor deposition fabrication of these organic light-emitting elements stacked on the substrate comprising the mask having engagement sections provided over a wide range on the surface facing the substrate corresponding to the distribution of the through holes, the substrate formed with corresponding structures to prevent positional slip of the vapor deposition mask in an in-plane direction by engaging the engagement sections of the mask.

The substrate is a plate shaped member formed of glass or resin, and it is possible to form layers such as electrodes and organic elements on the substrate. A plurality of organic light-emitting elements is formed on the substrate. The vapor deposition mask is used for vapor deposition formation of this plurality of organic light-emitting elements or some among the plurality of organic light-emitting elements. Specifically, through holes corresponding to the organic light-emitting elements are provided in the vapor deposition mask, a vapor deposition material that has been vaporized only at these sections, and vapor deposited on the substrate.

Engagement sections facing the substrate are provided in-plane in the vapor deposition mask. Also, structures for engaging with the engagement sections are provided in the substrate at places corresponding to the engagement sections. The engagement sections can be constructed having a plurality of pointed shapes arranged, constructed using a continuous elongated shape (beam shape, curved line shape etc.), or constructed as a combination of these. These types of engagement sections are arranged in the vapor deposition mask over a range having a two-dimensional span. Positional slip due to thermal expansion arises in respective in-plane directions, which means that the engagement sections for controlling this slip must also be arranged widely two-dimensionally. A specific arrangement interval can be determined based on the extent of positional slip, but generally speaking it is desirable for the minimum shape for including the engagement section is of such an extent to cover a wide range of vapor deposition masks. This is because the effect of preventing positional slip is high close to the inner and outer parts of this shape.

The vapor deposition mask is attached at a specified position on the substrate by engaging the engagement sections with corresponding engagement structures on the substrate. This positional relationship is fixed relative to the engagement position, and so is also held in the event of thermal expansion due to increase in temperature inside the vapor deposition unit. In particular, there is hardly any positional slip between the vapor deposition mask and the substrate in an in-plane direction close to engagement sections and between a plurality of engagement sections, which secures high vapor deposition precision.

Preferably, with the vapor deposition mask of the present invention, at least some of the engagement sections are arranged surrounding regions containing all through holes, to prevent positional slip between the substrate and the evaporation mask in an in-plane direction at an inner side. Surrounding the periphery of the region can also be carried out continuously, or by, for example, arranging engagement sections only at vertices of the region or by opening up a distance and performing at intervals. Regardless of the method employed, by surrounding the periphery the effect of preventing the positional slip between the substrate and the evaporation mask is increased. Also, other through holes on the vapor deposition mask and corresponding organic light-emitting elements on the substrate are not provided at a periphery of the through holes on the vapor deposition mask, and there is the advantage that it is easy to arrange engagement sections and corresponding structures on the substrate.

With the vapor deposition mask of the present invention, preferably a plurality of panels provided with a plurality of organic light emitting elements are formed at intervals on the substrate, and at least some of the engagement sections are provided at a position corresponding to between panels and surrounding a region corresponding to at least one panel, to prevent positional slip between the substrate and the vapor deposition mask in an in-plane direction inside regions surrounded by the engagement sections.

Specifically, a plurality of panels are formed on this substrate, finally separated and used as respective devices. Then, each panel is provided with a plurality of organic light-emitting elements. In this case, there are no through holes or organic light-emitting elements between panels. In the event that engagement sections are provided between panels, it is made difficult for restrictions on attachment position to be felt, and it is also possible to make engagement sections and corresponding substrate shaped structures more robust. It is therefore possible to effectively prevent positional slip between the substrate and the vapor deposition mask at a region surrounded by the engagement sections.

Preferably, with the vapor deposition mask of the present invention, at least some of the engagement sections are provided at positions corresponding to between each panel to surround a region corresponding to each panel, preventing positional slip between the substrate and the vapor deposition mask in an in-plane direction between each panel.

With the vapor deposition mask of the present invention, a plurality of panels provided with a plurality of organic light-emitting elements are preferably provided at intervals on the substrate, the vapor deposition mask is provided with flexible sections that are formed comparatively softly at a periphery and arranged along positions corresponding to between panels so that the vapor deposition mask is divided into a plurality of sections, and the engagement sections are arranged over a wide range corresponding to distribution of through holes inside each divided region, to prevent positional slip between the substrate and the vapor deposition mask in each region in an in-plane direction.

The flexible sections are curved compared to the periphery, and at sites constructed so that it becomes easy to deform due to compression and expansion, for example, they can be made by varying material or varying thickness of the vapor deposition mask. By making the flexible sections flexible there is the effect that it is easy to engage the engagement sections. There is also the effect that slip in an in-plane direction due to thermal expansion is absorbed. It is also possible to provide the flexible sections in the vapor deposition mask so as to divide a region corresponding to each panel, and to provide the flexible sections so that the vapor deposition mask itself is divided into a number of parts including one or a plurality of panels.

With the vapor deposition mask of the present invention, a plurality of pixels made up of a combination of a plurality of organic light-emitting elements having different colors of emitted light are preferably formed on the substrate, the vapor deposition mask is provided with through holes corresponding to a plurality of organic light-emitting elements having a particular color, and at least some of the engagement sections are provided at corresponding positions between pixels, surrounding a region corresponding to at least one pixel, to prevent positional slip between the substrate and the vapor deposition mask inside regions surrounded by the engagement sections in an in-plane direction. The engagement sections are provided in order to improve alignment precision in pixel units.

Preferably, with the vapor deposition mask of the present invention, the engagement sections engage with the corresponding structures on the substrate at to hold an adjacent substrate and the vapor deposition mask at an extremely close distance.

Preferably with the vapor deposition mask of the present invention, with respect to the engagement sections and corresponding structures on the substrate, one is a pointed cuspid shape, while the other is a corresponding widening indented shape, coming into contact with each other only at respective side surface formed in an inclined manner. The side surface can be linear, or can be a curved structure such as tracing a round shape. In order to increase abrasion resistance, it is also effective to cause a reduction in smoothness by making fine undulations on the surface of the side surface.

An organic LED of the present invention has a plurality of organic light emitting elements formed on a substrate by stacking a vapor deposition mask and carrying out vapor deposition processing, provided with engagement sections over a wide range corresponding to in-line distribution range of the organic light-emitting elements opposite the vapor deposition mask, for engaging with corresponding structures of the vapor deposition mask to prevent positional slip of the vapor deposition mask and the substrate in an in-plane direction.

A method of manufacturing an organic LED of the present invention is a method of manufacturing an organic LED using the vapor deposition mask, comprising the steps of engaging engagement sections of the vapor deposition mask with corresponding structures on the substrate of the organic LED to superimpose the vapor deposition mask and the substrate, and subjecting the superimposed vapor deposition mask and substrate to vapor deposition processing to form a vapor deposited organic light-emitting element on the substrate.

Using the technology of the present invention, vapor deposition processing for an organic LED realizes high precision in response to an engagement pattern distribution. In this way, for example, it becomes possible to manufacture a device having higher resolution than the related art with element intervals made narrower.

### BRIEF DESCRIPTION OF THE DRAWINGS

FIG. 1 is a plan view showing a structural example of a vapor deposition mask;

FIG. 2 is a cross sectional drawing for the case where vapor deposition is carried out with the vapor deposition mask of FIG. 1;

FIG. 3 is a plan view showing a structural example of another vapor deposition mask;

FIG. 4 is an enlargement of the vapor deposition mask of FIG. 3;

FIG. 5 is a cross sectional drawing for the case where vapor deposition is carried out with the vapor deposition mask of FIG. 3;

FIG. 6 is a plan view showing a structural example of yet another vapor deposition mask; and

FIG. 7 is a cross sectional drawing for the case where vapor deposition is carried out with the vapor deposition mask of FIG. 6.

### DESCRIPTION OF THE PREFERRED EMBODIMENT

In the following, three typical embodiments will be described. However, it goes without saying that the present invention is not limited to these embodiments.

### First Embodiment

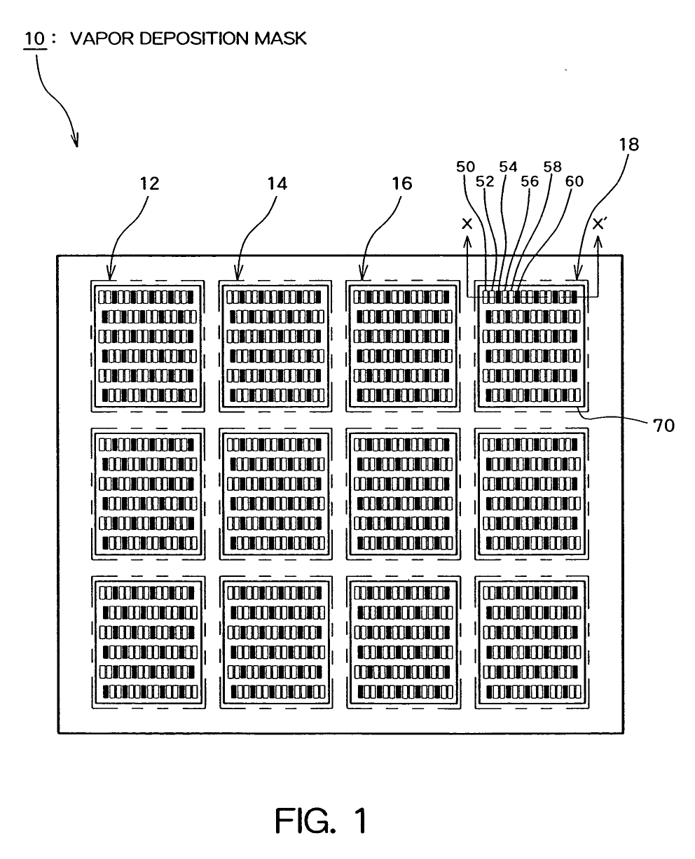

FIG. 1 is a plan view of a vapor deposition mask 10 of this embodiment. The vapor deposition mask 10 is made by processing a thin flat plate of metal. INVAR or Ni—Co, known as low expansion alloys are used as the metal.

The vapor deposition mask 10 is used as a mask for forming 12 color panels on a substrate, and in a vapor deposition process surfaces shown in the drawings are overlapped facing the substrate. Regions 12, 14, 16, 18, . . . correspond to each panel, and a total of 12 regions, arrayed in 4 vertical rows of 3, are arranged slightly apart.

Each panel is provided with a plurality of cells, made up of organic light-emitting elements of the three colors R (red), G (green) and B (blue). Each organic light-emitting element is then formed by carrying out vapor deposition of an organic layer corresponding to each of these colors. The vapor deposition mask 10 is for forming organic light-emitting elements of R, among these colors. Specifically, among the 3 colors of RGB, through holes are provided in sections corresponding to the organic light-emitting elements of R, and holes are not formed at sections corresponding to the organic light-emitting elements of the two remaining colors GB.

In order to show a through hole pattern for each organic light emitting element, FIG. 1 shows not only the through holes corresponding to the R organic light emitting elements, but also arrangement of G and B organic light-emitting elements not provided with holes. For example, in the upper right region 18, small regions 50, 52, 54, 56, 58, 60, . . . corresponding to each of the colors B, G and R are shown in order from the left in the upper most row. The small regions 50, 52, 54 and 56, 58, 60, respectively constitute one pixel. Also, the small regions 54 and 60 corresponding to R represent respective through holes 54, 60.

A convex projection structure as engagement sections is provided around an outer edge in regions corresponding to each panel. This structure is made in a rectangular shape surrounding the entire pattern corresponding to the organic light-emitting elements, as shown by the reference numeral 70 in region 18.

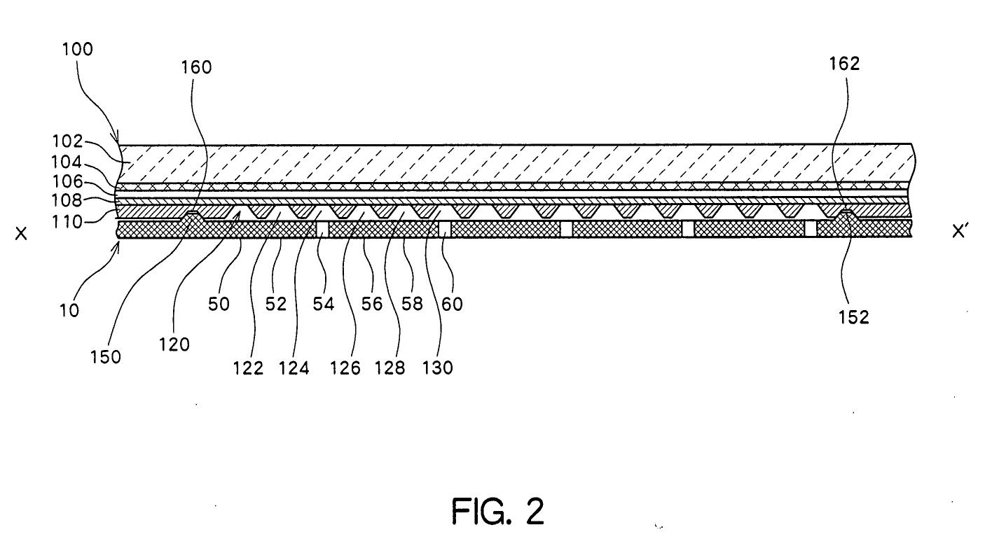

FIG. 2 is a drawing showing a cross section along XX′ in FIG. 1, in a vapor deposition process. Here, the vapor deposition mask 10 is superimposed on the substrate 100. To hold this, an electromagnet, not shown, is used at an upper side of the substrate 100.

The substrate 100 includes a glass substrate 102, and a plurality of layers 104, 106, 108, 110 provided beneath the glass substrate 102. The layers 104, 106, 108 are equivalent, for example, to an ITO electrode layer, a hole injection layer, and a hole transportation layer. However, as is well known, which layer an organic LED is formed on is arbitrary, and the laminated layer pattern shown in the drawing is only one example.

The layer 110 is provided in order to separate the formed organic light emitting elements. Specifically, the layer 110 is provided at sections where organic light-emitting layers are not provided. In more detail, formation of a B color element 120, a G color element 122, an R color element 124, a B color element 126, a G color element 128, an r color element 130, . . . is carried out corresponding to pattern of the small regions 50, 52, 54, 56, 58, 60, . . . shown in FIG. 1.

The vapor deposition mask 10 is for forming the R organic light emitting elements. Therefore, as described with FIG. 1, through holes 54, 60 are only formed at the small regions 54, 60 corresponding to R, and holes are not formed at the small regions 50, 52, 56, 58 corresponding to B and G.

Convex sections 150, 152 having a convex projecting cross section shown by reference numeral 70 in FIG. 1 are provided on an upper surface of the vapor deposition mask 10. The size of these concave sections is, for example, 2 μm in height and 10 μm in width. Obviously this size is not limiting, and can be suitable set according to the required strength. On the other hand, corresponding concave section 160, 162 are provided on the layer 110 constituting a lower surface of the substrate 100. The convex sections 150, 152 have a trapezoid shape with tips (upper side of the drawing) becoming narrower, while the concave sections 160, 162 have a trapezoid shape with tips (lower side of the drawing) becoming wider. These sections are then engaged with each other by coming into contact only at inclined side surfaces of the trapezoid shapes. That is, other at than the side surfaces of the trapezoid shapes, the vapor deposition mask 10 and the substrate 100 are held without contacting each other. This is in order to prevent damage to the structure of the organic light emitting elements formed on the substrate 100, using the vapor deposition mask 10. However, if the distance between the vapor deposition mask 10 and the substrate 100 is large, the effect of the mask will be reduced. For this reason the distance between the vapor deposition mask 10 and the substrate 100 is set to about 10 μm or less.

The substrate 100 and the vapor deposition mask 10 are positioned at an engagement position by control etc. using a CCD camera. The vapor deposition mask 10 is then sucked against the lower surface of the substrate 100 using an electromagnet provided on the back of the 100, and the two are engaged.

In this vapor deposition process, the vapor deposition mask 10 exhibits thermal expansion due to heat accompanying heating of the organic material. Also, the substrate 100 is held at a comparatively low temperature s it is positioned on the back of the vapor deposition mask 10, but because of the characteristics of the material exhibits larger thermal expansion than the vapor deposition mask 10. However, there is no positional slip of the through holes 54, 60 corresponding to the R color elements 124, 130. This is because on both sides, the convex section 150 and the concave section 160, and the convex section 152 and the concave section 162 are respectively engaged, to prevent slip in the horizontal direction.

With this structure, the extent of positional slip is constrained to a small error within each panel region. Also, the effect of thermal expansion of each panel is not passed on to other panels. Therefore, even in the event that some engagements come apart for whatever reason, the effect of this will not affect other regions. It is therefore possible to realize highly precise vapor deposition processing.

In a vacuum vapor deposition unit, formation of organic light-emitting elements for each of the colors B and G is similarly carried out. Specifically, when carrying out formation of a light emitting layer for the B color elements 120, 126, . . . instead of the vapor deposition mask 10 a vapor deposition mask provided with through holes only at small regions 50, 56 . . . corresponding to B is used. Also, when carrying out formation of a light emitting layer for the G color elements 122, 128 . . . , a vapor deposition mask provided with through holes only at small regions 52, 58 . . . corresponding to G is used. With these vapor deposition masks, engagement sections are preferably provided at the same positions as with the vapor deposition mask 10, and in this way the wasteful process of forming a plurality of corresponding engagement structures on the substrate 100 can be omitted.

Here, convex projecting structures are provided as engagement sections on the side of the vapor deposition mask 10, and concave structures are provided on the substrate 100 side as corresponding structures. However, this format is not particularly limiting as long as engagement is possible. For example, it is also possible to have concave shapes at the vapor deposition mask 10 side and convex shapes at the substrate 100 side. It is also effective to have the convex shapes of material having a comparatively large coefficient of thermal expansion, and the concave sections of a material having a comparatively small coefficient of thermal expansion, to give strong engagement at the time of thermal expansion. Also, various settings are possible for the cross sectional shape, and it is not limited to the trapezoid shape shown, and it is also possible to have a rectangular shape or a curved shape tracing a circle. Preferably, the cross sections are determined theoretically or by experimentation of angle of attack and curvature, so that engagement is initially easy, with separation becoming difficult when excessive force is applied in the horizontal direction during vapor deposition processing,

### Second Embodiment

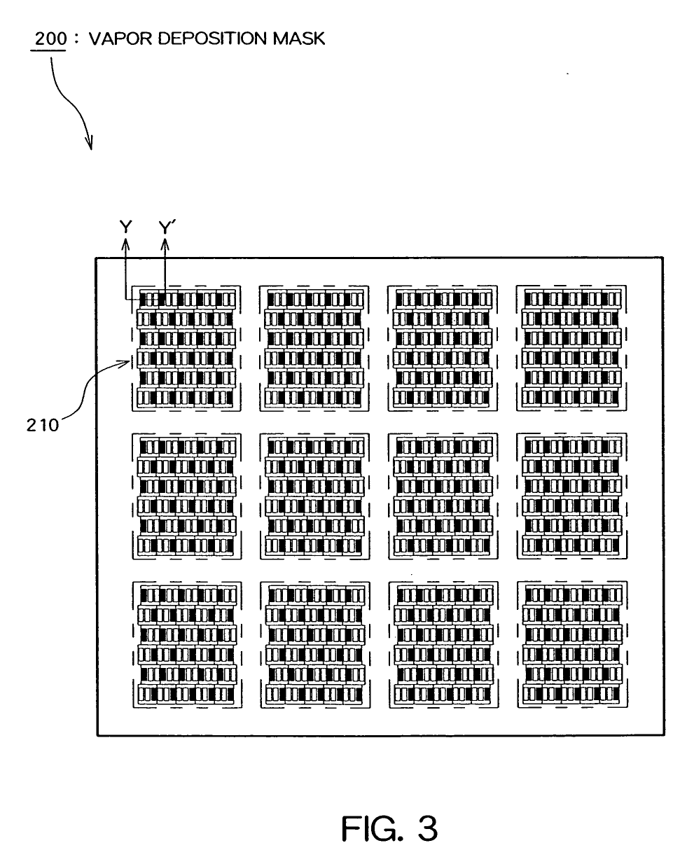

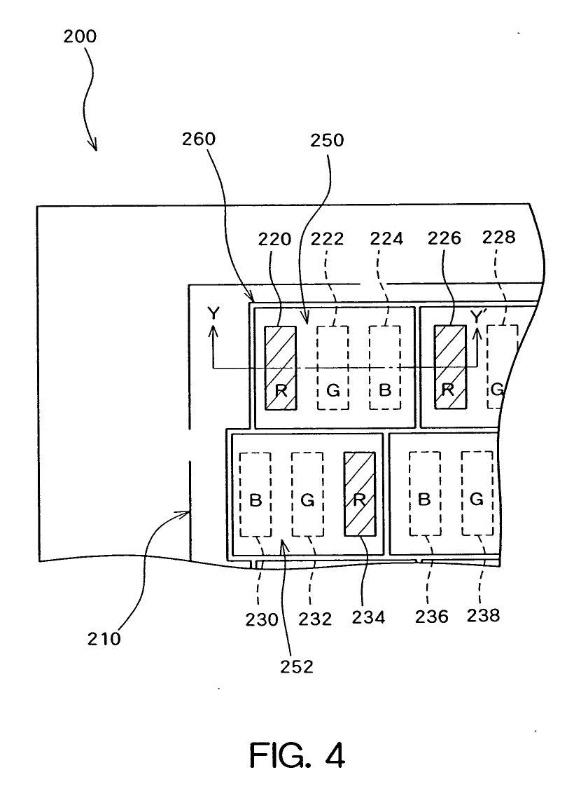

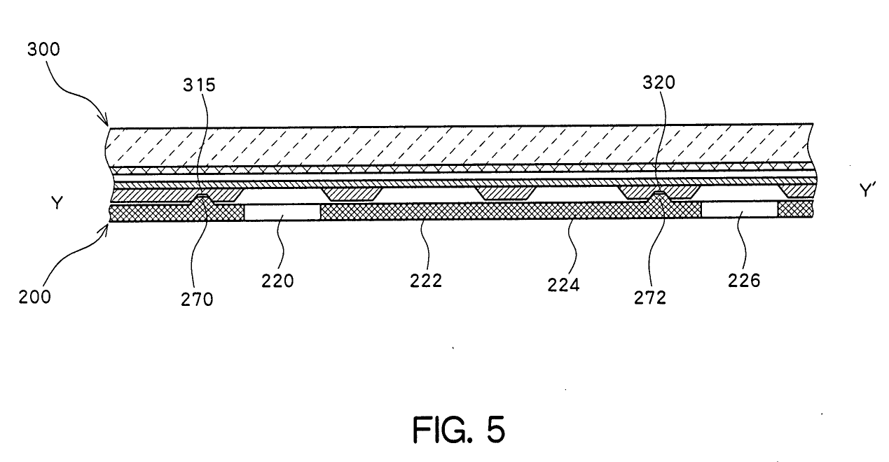

Next, a second embodiment will be described using FIG. 3, FIG. 4 and FIG. 5. This embodiment is the same as the first embodiment with respect to formation of an organic LED panel using vapor deposition. Description of structures that are the same will therefore be omitted or simplified, and detailed description will focus on the characteristic points of this embodiment.

FIG. 3 is a plan view of a vapor deposition mask 200, and corresponds to FIG. 1. FIG. 4 is an enlargement of FIG. 3, and shows the upper vicinity of a panel corresponding region 210 of FIG. 3 in detail. FIG. 5 is a cross sectional drawing showing an element used by the vapor deposition mask 200 in vapor deposition of the substrate 300, taken along YY′ in FIG. 3 or FIG. 4, and corresponds to FIG. 2.

Small regions corresponding to each organic light-emitting element formed on the substrate 300 are shown on the vapor deposition mask 200. For example, in FIG. 4, there are shown small regions 220, 226, 234 corresponding to R organic light emitting elements, small regions 222, 228, 232, 238 corresponding to G organic light-emitting elements, and small regions 224, 230, 236 corresponding to B organic light-emitting element. The vapor deposition mask 200 is used for vapor deposition formation of an organic layer for R organic light-emitting elements. For this reason, the small regions 220, 226234 corresponding to the R organic light-emitting elements constitute through holes 220, 226, 234.

With this organic LED, the RGB organic light-emitting elements are superimposed to realize multiple color pixels. That is, the small regions 220, 222, 224 contain a pixel region 250 corresponding to one set of pixels, and the small regions 230, 232, 234 include a pixel region 252 corresponding to another set of pixels.

In this embodiment, in order to prevent horizontal slip between the vapor deposition mask 200 and the substrate 300 in each pixel, a characteristic point is that an engagement structure is provided in the vicinity of each pixel. Specifically, as shown by reference numeral 260 in FIG. 4, the structures extending in a straight line vertically and horizontally form a lattice, surrounding each pixel.

The format of respective engagement structures is the same as for embodiment 1. Specifically, as shown in FIG. 5, convex sections 270, 272, being convex projections, are formed on the upper surface of the vapor deposition mask 200, while corresponding concave sections 315, 320 are formed on the lower surface of the substrate 300.

As will be understood from FIG. 4 and FIG. 5, a distance between, for example, a small region 224 and a small region 226 that correspond to different pixels is set slightly larger compared to a distance between, for example, a small region 222 and a small region 224 that correspond to the same pixel. That is, a formation interval for organic light-emitting elements is different for within pixels and outside pixels. However, if it is possible to make engagement structures small, it is possible to make formation intervals for all organic light-emitting elements equal.

Combinations of BGR organic light-emitting elements constituting a pixel are arbitrary. For example, in FIG. 4, three organic light-emitting elements corresponding to small regions 222, 224 and 226 can be considered as one pixel unit. That is, a pixel is not a combination of three particular organic light-emitting elements determined by a circuit or electrical signals, but can be considered as indicating a combination of three organic light-emitting elements that are close together.

### Third Embodiment

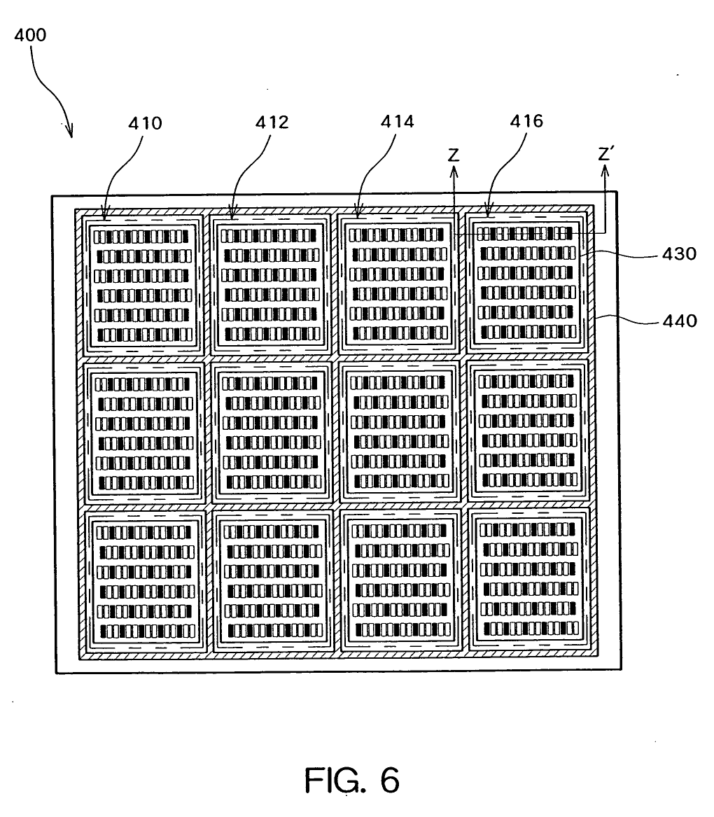

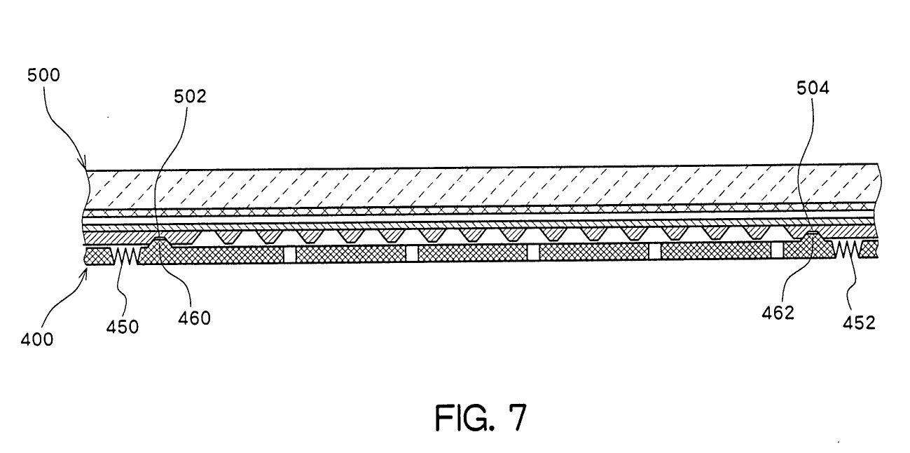

Next, a third embodiment will be described using FIG. 6 and FIG. 7. This embodiment is the same as embodiment 1 with respect to formation of an organic LED panel using vapor deposition. Description of similar structures will therefore be omitted or simplified, and detailed description will be given for characteristic points of this embodiment.

FIG. 6 is a plan view of a vapor deposition mask 400, and corresponds to FIG. 1. Also, FIG. 7 is a cross sectional drawing showing an element used by the vapor deposition mask 400 in vapor deposition of the substrate 500, taken along ZZ′ in FIG. 6, and corresponds to FIG. 2.

Twelve panels are formed on the substrate 500, and there are 12 regions 410, 412, 414, 416 . . . corresponding to the vapor deposition mask 400. Convex projecting structures are formed close to the outer edges of these regions as engagement sections. For example, a convex projecting structure represented by reference numeral 430 is provided inside the region 416, close to its outer edge. This aspect is the same as described with embodiment 1.

The characteristic point of this embodiment is that each of the regions 410, 412, 414, 416, . . . corresponding to the panel are surrounded by a flexible section 440 provided in a lattice shape. Alternatively, each of the regions 410, 412, 414, 416, . . . can be considered to be partitioned and isolated by the flexible section 440.

The flexible section 440 is given more resilience than the other regions in the vapor deposition mask by changing the elements or structures etc. to be deformed, and is a structure formed so that it is easy to bend. Wrinkled sections 450, 452, that are the cross section of the flexible section 440, are shown in FIG. 7. The wrinkled section 450, 452 are thinner than the periphery, and have a structure folded at short intervals. Because of this structure, in the event that a force is made to act within the vertical cross section, it is easy for the wrinkled sections 450, 452 to be deformed by compressions and bending, and it is possible to easily restore to the original shape when the force is removed. By adopting this flexible section 440, the process of engaging the vapor deposition mask 400 with the substrate 500 is simplified. This is because microscopic structural errors in the engagement structures can be absorbed.

In this structure, in the event that the vapor deposition mask 400 and the substrate 500 thermally expand by differing amounts during vapor deposition processing, horizontal positional slip between the two is prevented in each panel by the engagement structures. For example, as shown in FIG. 7, on the vapor deposition mask 400 convex sections 460, 462 are provided at inner sides of the winkled sections 450, 452, and they engage with corresponding concave sections 502, 504 of the substrate 500. Positional slip between the two inside a panel is therefore prevented.

Positional slip of each panel is absorbed by carrying out warping deformation of the vapor deposition mask 400 or substrate 500 between engagement structures. The effects of deformation of each panel are generally also imparted to adjacent panels. However, in this embodiment, since the effect is efficiently absorbed by the flexible section 440 flexing, the effect of adjacent panels is removed. Specifically, in the flexible section 440, slip force acting on sections of the vapor deposition mask 400 other than the flexible section 440 and on the substrate 500 is reduced, and as well as the effect of making it unlikely that engagement between the vapor deposition mask 400 and the substrate 500 will come apart, there is the advantage that it is possible to make the total strength of the vapor deposition mask 400 and the substrate 500 smaller.

The invention has been described in detail with particular reference to certain preferred embodiments thereof, but it will be understood that variations and modifications can be effected within the spirit and scope of the invention.

### Parts List

10 deposition mask
12 region
14 region
16 region
18 region
50 small region
52 small region
54 small region
56 small region
58 small region
60 small region
70 organic light emitting elements
100 substrate
102 glass substrate
104 layer
106 layer
108 layer
110 layer
120 color element
122 color element
124 color element
126 color element
128 color element
130 color element
150 convex section
152 convex section
160 concave section
162 concave section
200 vapor deposition mask
210 region
220 small region
222 small region
224 small region
226 small region
228 small region
230 small region
232 small region
234 small region
236 small region
238 small region
250 pixel region
252 pixel region
260 structure
270 convex projection
272 convex projection
300 substrate
315 concave section
320 concave section
400 vapor deposition mask
410 region
412 region
414 region
416 region
430 convex projecting structure
440 flexible section
450 wrinkled sections
452 wrinkled sections
460 convex section
462 convex section
500 substrate
500 substrate
502 concave section
504 concave section

1. A plate-shaped vapor deposition mask for use with an OLED substrate, the mask is provided with through holes corresponding to a plurality of organic light-emitting elements formed on the substrate, used in vapor deposition fabrication of these organic light-emitting elements stacked on the substrate comprising the mask having engagement sections provided over a wide range on the surface facing the substrate corresponding to the distribution of the through holes, the substrate formed with corresponding structures to prevent positional slip of the vapor deposition mask in an in-plane direction by engaging the engagement sections of the mask.

2. The vapor deposition mask of claim 1, wherein at least some of the engagement sections are arranged surrounding a region including all of the through holes, to prevent positional slip between the substrate and the vapor deposition mask inside that region in an in-plane direction.

3. The vapor deposition mask of claim 1, further including a plurality of panels on which a plurality of organic light-emitting elements have been formed provided apart from one another on the substrate, and wherein at least some of the engagement sections are provided at corresponding positions between panels, surrounding a region corresponding to at east some of the panels, to prevent positional slip between the substrate and the vapor deposition mask inside regions surrounded by the engagement sections in an in-plane direction.

4. The vapor deposition mask of claim 3, wherein at least some of the engagement sections are provided at corresponding positions between each panel, surrounding a region corresponding each panel, to prevent positional slip between the substrate and the vapor deposition mask in each panel in an in-plane direction.

5. The vapor deposition mask of claim 1, wherein
a plurality of panels on which a plurality of organic light-emitting elements have been formed are provided apart from one another on the substrate,
the vapor deposition mask is provided with flexible sections that are formed comparatively softly at a periphery and arranged along positions corresponding to between panels so that the vapor deposition mask is divided into a plurality of sections, and
the engagement sections are arranged over a wide range corresponding to distribution of through holes inside each divided region, to prevent positional slip between the substrate and the vapor deposition mask in each region in an in-plane direction.

6. The vapor deposition mask of claim 1, wherein
a plurality of pixels made up of combinations of a plurality of organic light-emitting elements of differing color are formed on the substrate,
the vapor deposition mask is provided with through holes corresponding to a plurality of organic light-emitting elements having a particular color; and
at least some of the engagement sections are provided at corresponding positions between pixels, surrounding a region corresponding to at least one pixel, to prevent positional slip between the substrate and the vapor deposition mask inside regions surrounded by the engagement sections in an in-plane direction.

7. The vapor deposition mask of claim 6, wherein at least some of the engagement sections are provided at corresponding positions between each pixel, surrounding a region corresponding each pixel, to prevent positional slip between the substrate and the vapor deposition mask in each pixel in an in-plane direction.

8. The vapor deposition mask of claim 1, wherein the engagement sections engage with corresponding structures on the substrate at distances holding the adjacent substrate and the vapor deposition mask out of contact.

9. The vapor deposition mask of claim 8, wherein with respect to the engagement sections and corresponding structures on the substrate, one is a pointed cuspid shape, while the other is a corresponding widening indented shape, coming into contact with each other only at respective side surface formed in an inclined manner.

10. An organic LED having a plurality of organic light emitting elements formed on a subject by staking a vapor deposition mask and carrying out vapor deposition processing, provided with engagement sections over a wide range corresponding to in-line distribution range of the organic light-emitting elements opposite the vapor deposition mask, for engaging with corresponding structures of the vapor deposition mask to prevent positional slip of the vapor deposition mask and the substrate in an in-plane direction.

11. A method of manufacturing an organic LED using the vapor deposition mask of claim 1, comprising:
engaging engagement sections of the vapor deposition mask with corresponding structures on the substrate of the organic LED to superimpose the vapor deposition mask and the substrate, and
subjecting the superimposed vapor deposition mask and substrate to vapor deposition processing to form a vapor deposited organic light-emitting element on the substrate.
